(19) United States
(12) Patent Application Publication
(10) Pub. No.: US 2019/0013650 A1
(43) Pub. Date: Jan. 10, 2019

(54) MULTIPLEXED LASER LIGHT SOURCE

(71) Applicant: SHIMADZU CORPORATION, KYOTO (JP)

(72) Inventors: Jiro SAIKAWA, KYOTO (JP); Junki SAKAMOTO, KYOTO (JP)

(73) Assignee: SHIMADZU CORPORATION, KYOTO (JP)

(21) Appl. No.: 16/067,008

(22) PCT Filed: Jan. 8, 2016
(86) PCT No.: PCT/JP2016/050428

§ 371 Date: Jun. 28, 2018

(51) Int. Cl. H01S 5/40; G02B 6/42; H01S 5/022

(52) U.S. Cl. CPC H01S 5/4012; H01S 5/02236; H01S 5/4087; G02B 6/42

(57) ABSTRACT

A combined-wave laser light source comprises a two-dimensional laser light source 1 in which laser light sources are arranged two-dimensionally along a common plane, and a two-dimensional deflection optic element that is arranged corresponding to the two-dimensional laser light source 1 and which has an x-direction steering optic element 3 that deflects each laser optic axis of the two-dimensional laser light source in an x-direction and a y-direction steering optic element 4 that deflects each laser optic axis of the two-dimensional laser light source in a y-direction; and a combining lens 5 that converges the laser lights from the two-dimensional deflection optic elements, 3, 4 to combine said laser lights to an optical fiber.

### CROSS REFERENCE TO RELATED APPLICATIONS

This application relates to, and claims priority from, Ser. No.: PCT/JP2016/050428 filed Jan. 8, 2016, the entire contents of which are incorporated herein by reference.

### FIGURE SELECTED FOR PUBLICATION

FIG. 1

### BACKGROUND OF THE INVENTION

### Field of the Invention

The present invention relates to a multiplexed (combined-wave) laser light source that provides high-intensified laser by combining laser beams lights from a plurality of laser sources which is independent from one another. Further, the present invention relates to an exposure device, a processing machine, an illumination device and a medical equipment (device), of which a light source is the multiplexed (combined-wave) laser light source set forth above.

### Description of the Related Art

Conventionally, a method by which a plurality of lasers from a plurality of light sources is combined into one optical fiber, and a method by which that fibers connecting a plurality of light sources are bundled to form one fiber (Patent Document 1).

In addition, the beams that are emitted in the different direction from the optic axis of the converging optic system among a plurality of beams of a plurality of semiconductor lasers that are air-tightly packaged to provide a high-brightness are deflected toward the optic axis direction to be incident to the converging optic system. and the beams converged by the converging optic system are specified to be incident into a fiber to form the combined-wave.

### RELATED PRIOR ART DOCUMENTS

### Patent Documents

Patent Document 1: JP Patent Published 2002-202442 A
Patent Document 2: JP Patent Published 2007-17925 A

### ASPECTS AND SUMMARY OF THE INVENTION

### Problems to be Solved by the Invention

However, according to the patent document 2, each of a plurality of packaged semiconductor lasers is in-place in the respectively different locations and each of the plurality of semiconductor lasers is arranged three-dimensionally. Accordingly, the adjustment to arrange three-dimensionally the plurality of optic axes of semiconductor lasers takes time for such adjustment and results in a cost increase.

In addition, the semiconductor laser generates heat so that the semiconductor laser must be subjected to heat-dissipation using a heat sink. However, given the number of the semiconductor lasers increases, more heat-dissipation is needed, so that the structure of the heat-sink can be further complex.

The purpose of the present invention is to provide a combined-wave (multiplexing) laser light source that facilitates to adjust the optic axes of laser light sources and can cut the adjusting cost.

### Means for Solving the Problem

For solving the above problem, a combined-wave (multiplexed) laser light source, according to the present invention, comprises; a two-dimensional laser light source (a laser light source arrayed along a plane) in which laser light sources are arranged two-dimensionally, a two-dimensional deflection optic element that is arranged corresponding to the two-dimensional laser light source and has an x-direction steering optic element that deflects each laser optic axis of the two-dimensional laser light source in an- x-direction and a y-direction steering optic element that deflects each laser optic axis of the two-dimensional laser light source in a y-direction; and a combining (coupling) lens that converges laser lights from the two-dimensional deflection optic element to combine to an optical fiber.

### Effect of the Invention

According to the aspect of the present invention, the laser light sources that are arranged on the two-dimensional plane can limit an optic axis adjustment on the same plane, so that the optic axes of the two-dimensional laser light sources can be easily adjusted. Accordingly, the cost for such adjustment can be cut by such as an automation therefor and so forth. In addition, the two-dimensional deflection optic element deflects each laser optic axis of the two-dimensional laser light sources in the x-direction and the y-direction, and the combining lens converges the laser lights from the two-dimensional deflection optic element such laser lights to combine. Accordingly, the light beam can be highly densified (highly concentrated) to attain a high-power output.

The above and other aspects, features and advantages of the present invention will become apparent from the following description read in conjunction with the accompanying drawings, in which like reference numerals designate the same elements.

### BRIEF DESCRIPTION OF THE DRAWINGS

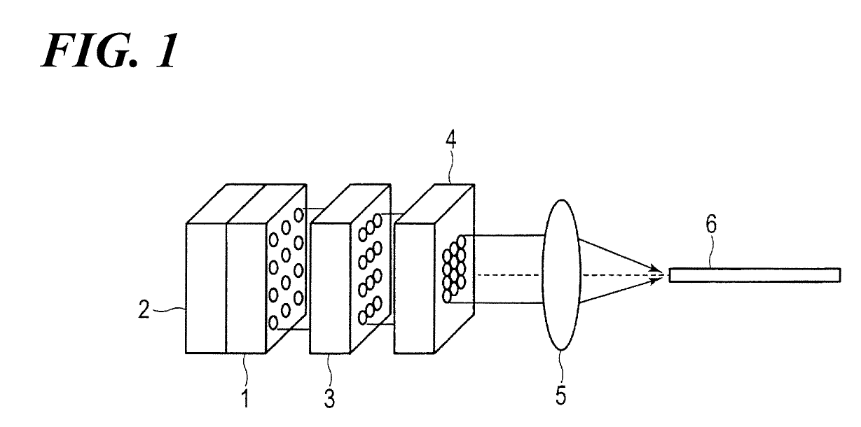

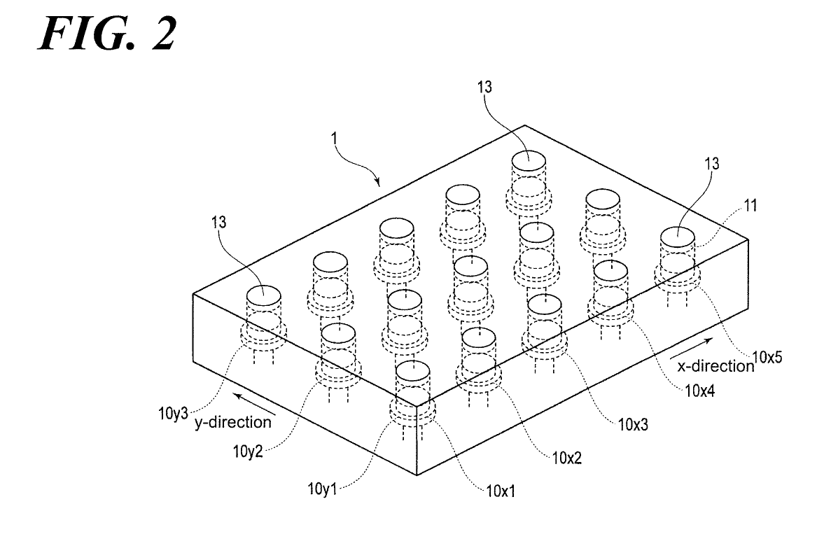

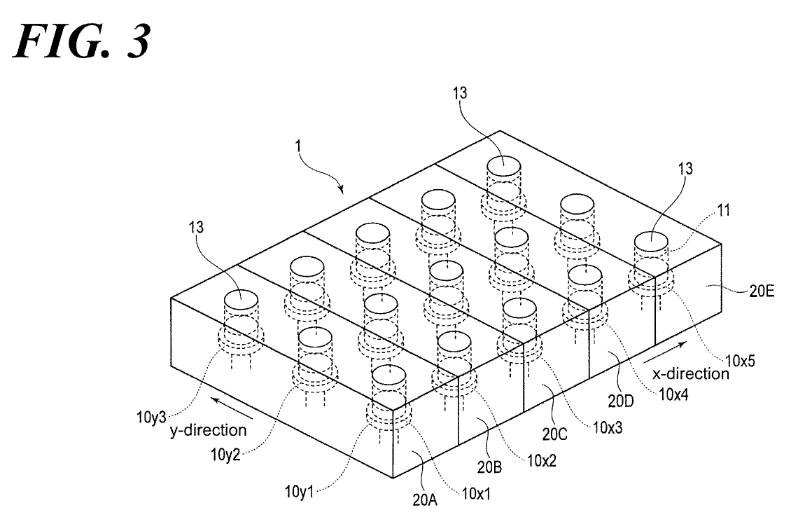

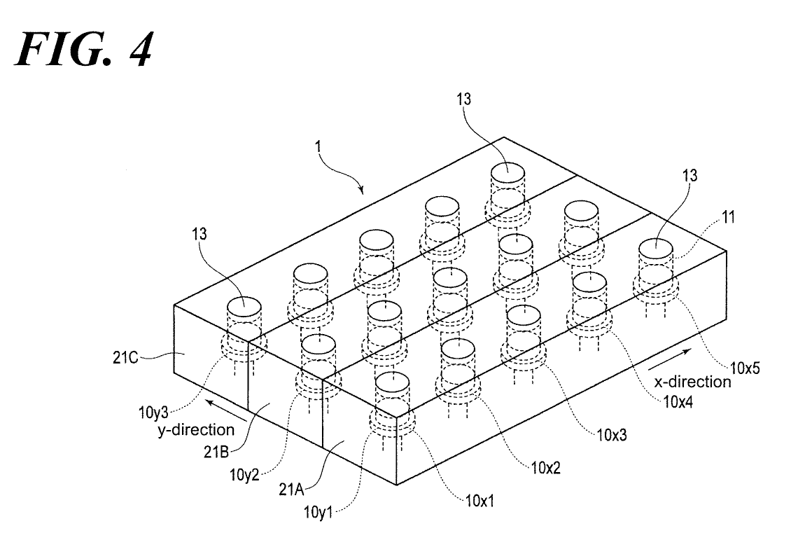

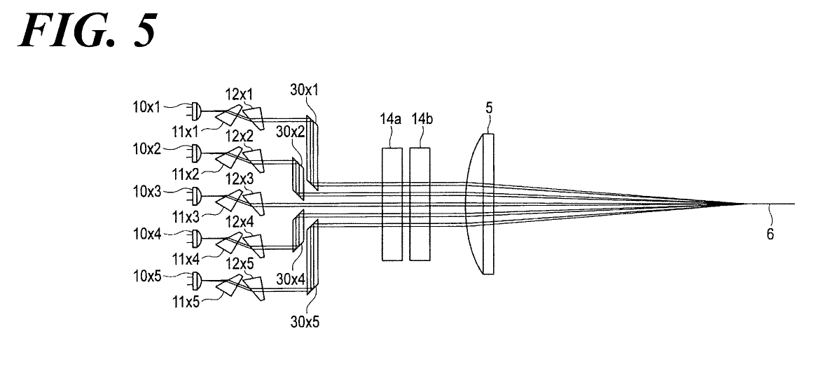

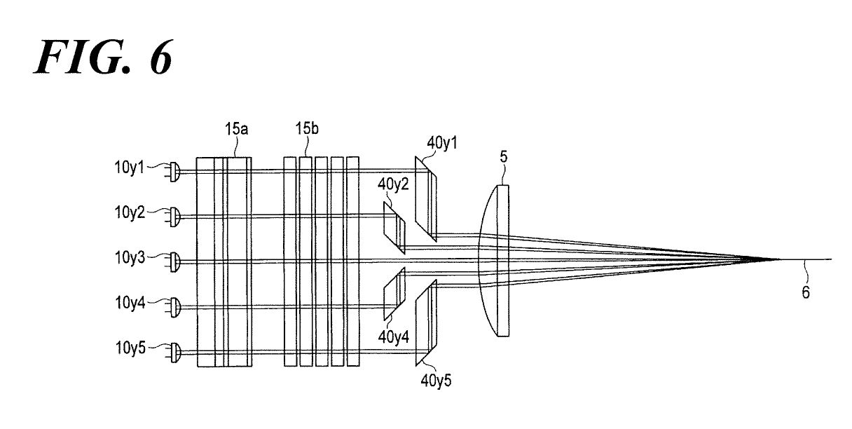

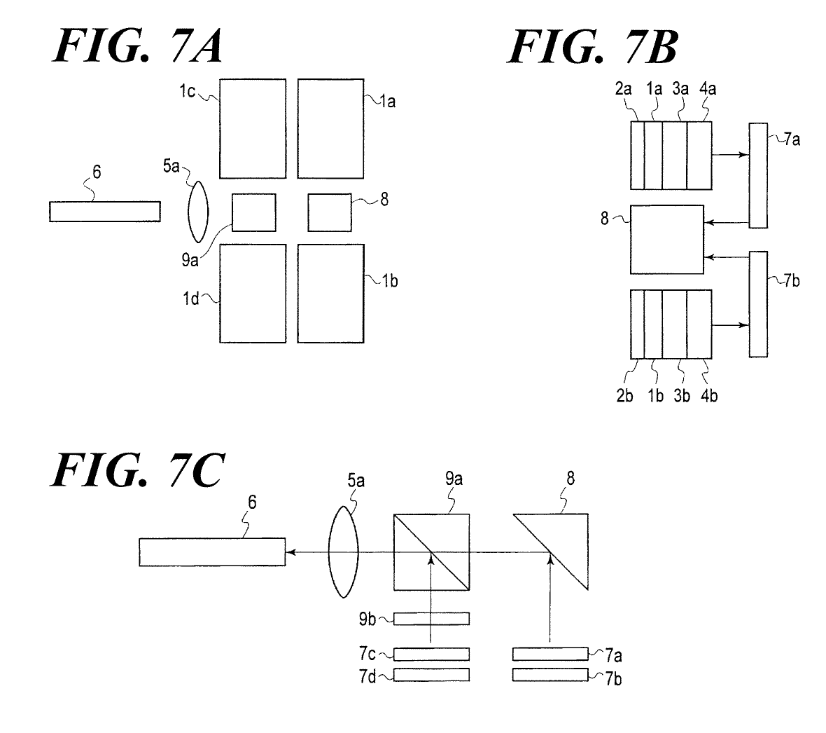

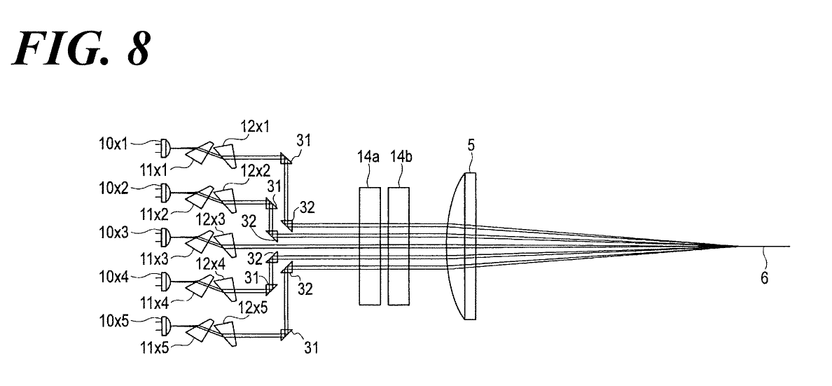

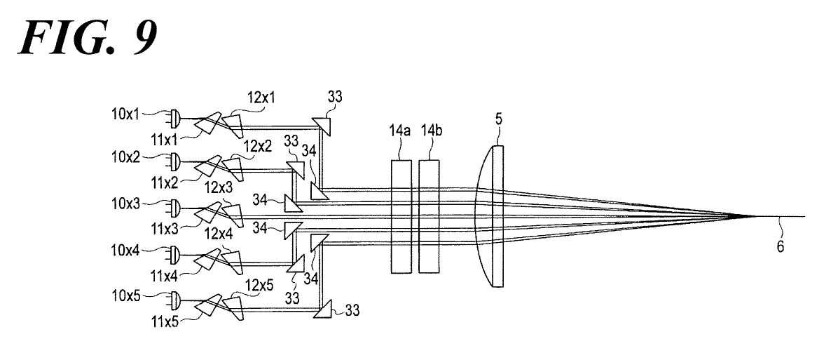

FIG. 1 is a diagram illustrating the structure of a combined-wave laser light sources according to the aspect of the Embodiment 1 of the present invention.

FIG. 2 is a diagram illustrating the detail structure of the two-dimensional laser mount unit using CAN (packed like a can) type semiconductor laser as the combined-wave laser light sources according to the aspect of the Embodiment 1 of the present invention.

FIG. 3 is a diagram illustrating the detail structure of the two-dimensional laser mount unit divided using CAN type semiconductor laser in the x-direction as the combined-wave laser light sources according to the aspect of the Embodiment 1 of the present invention.

FIG. 4 is a diagram illustrating the detail structure of the two-dimensional laser mount unit divided using CAN type semiconductor laser in the y-direction as the combined-wave laser light sources according to the aspect of the Embodiment 1 of the present invention.

FIG. 5 is a block diagram illustrating the x-direction steering optic element of the combined-wave laser light sources according to the aspect of the Embodiment 1 of the present invention.

FIG. 6 is a block diagram illustrating the y-direction steering optic element of the combined-wave laser light sources according to the aspect of the Embodiment 1 of the present invention.

FIG. 7A-7C are block diagrams illustrating a combined-wave laser light sources according to the aspect of the Embodiment 2 of the present invention.

FIG. 8 is a block diagram illustrating the x-direction steering optic element of the combined-wave laser light sources according to the aspect of the alternative example of the Embodiment 1 of the present invention.

FIG. 9 is a block diagram illustrating the x-direction steering optic element of the combined-wave laser light sources according to the aspect of the other alternative example of the Embodiment 1 of the present invention.

### DETAILED DESCRIPTION OF THE PREFERRED EMBODIMENTS

Reference will now be made in detail to embodiments of the invention. Wherever possible, same or similar reference numerals are used in the drawings and the description to refer to the same or like parts or steps. The drawings are in simplified form and are not to precise scale. The word ‘couple’ and similar terms do not necessarily denote direct and immediate connections, but also include connections through intermediate elements or devices. For purposes of convenience and clarity only, directional (up/down, etc.) or motional (forward/back, etc.) terms may be used with respect to the drawings. These and similar directional terms should not be construed to limit the scope in any manner. It will also be understood that other embodiments may be utilized without departing from the scope of the present invention, and that the detailed description is not to be taken in a limiting sense, and that elements may be differently positioned, or otherwise noted as in the appended claims without requirements of the written description being required thereto.

Various operations may be described as multiple discrete operations in turn, in a manner that may be helpful in understanding embodiments of the present invention; however, the order of description should not be construed to imply that these operations are order dependent.

It will be further understood by those of skill in the art that the apparatus and devices and the elements herein should be understood as fully operational and without limitation, and including the sub components such as operational structures, circuits, communication pathways, control switches, and related elements, any necessary elements, inputs, sensors, detectors, processors and any combinations of these structures etc. as will be understood by those of skill in the art as also being identified as or capable of operating the systems and devices and subcomponents noted herein and structures that accomplish the functions without restrictive language or label requirements since those of skill in the art are well versed in related light-emitting device fields, laser circuits, data transmission systems and operational controls and technologies of laser devices and all their sub components, including various transmission arrangements and combinations without departing from the scope and spirit of the present invention.

Referring to FIGs., the inventors set forth the Embodiments of the present invention. Referring to FIGs, the same or similar element has the same or similar sign. However, it must be paid attention that FIGs are schematic. In addition, hereinafter, the aspect of the Embodiment is an example to specify the technology aspect of the present invention and the structure and the arrangement of the components are not limited to the aspect of the Embodiment. The aspect of the Embodiment of the present invention can be modified in a variety of aspects within the scope of claimed claims of the present invention.

Hereinafter, referring to FIGs., the inventors set forth the detail of a laser device according to the aspect of the Embodiment of the present invention.

### Embodiment 1

FIG. 1 is a diagram illustrating the structure of a combined-wave laser light sources according to the aspect of the Embodiment 1 of the present invention. Referring to FIG. 1. the combined-wave laser light source comprises a two-dimensional laser mount element 1, a heat sink 2, an x-direction steering optical element 3, ay-direction steering optical element 4, a converging lens 5 and an optical fiber 6.

In addition, an optic element such as a telescope can be installed between the y-direction steering optical element 4 and the converging lens 5. Based on such aspect, the property such as a beam size can be modified.

The two-dimensional laser mount unit 1 forms a tabular shape corresponding to the two-dimensional laser light sources of the present invention, and referring to FIG. 2, consists of a plurality of semiconductor lasers 10x1-10xm, a plurality of semiconductor lasers 10y1-10yn and a plurality of lenses 11 facing each semiconductor laser that are arranged in the x-direction and y-direction, i.e.., two-dimensionally arranged. The plurality of semiconductor lasers 10x1-10xm are arranged every predetermined interval in the x-direction (horizontal direction) (in such instance, m=5) and the plurality of semiconductor lasers 10y1-10yn are arranged every predetermined interval in the y-direction (vertical direction) (in such instance, n=3).

Each of semiconductor lasers 10x1-10xm, 10y1-10yn that consist of a laser diode is excited by the injection of a charge carrier having an electron and a hole injected by driving an electric current, and then outputs the laser light emitted due to conductive emission emerged when the pair of charge carriers of the injected electron and hole decays. A CAN type semiconductor laser is applied to such semiconductor laser. In addition, semiconductor laser is not limited to such CAN type semiconductor laser.

With respect to a plurality of semiconductor lasers 10x1-10xm, 10y1-10yn, the semiconductor lasers and the collimate lenses 11 corresponding to such semiconductor lasers are unified and fixed by the adjustable holder. With respect to an edge-emitting semiconductor laser, the anamorphic prism pair or a cylindrical lens pair can be added for a beam shaping.

In addition, the two-dimensional laser mount unit 1 comprises a through-hole 13 at the position facing each collimate lens on the surface thereof; and each through-hole 13 outputs the laser light from each of semiconductor lasers 10x1-10xm via the collimate lens 11 to the x-direction steering optic element 3 and outputs the laser light from each of semiconductor lasers 10y1-10yn to the y-direction steering optic element 4.

The heat sink 2 that consists of a heat dissipation plate (heat sink), which dissipates the heat generated in the two-dimensional laser mount unit 1, has a tabular shape and arranged so as to contact or close to the two-dimensional laser mount unit 1. A metal having a heat-transfer property, such as aluminum, iron, copper and brass and so forth, is applied to the heat sink 2.

In addition, referring to FIG. 3, the divided mount units 20A-20E that are formed by dividing the two-dimensional laser mount unit 1 to a plurality of units in the x-direction. Or, referring to FIG. 4, the divided mount units 21A-21C that are formed by dividing the two-dimensional laser mount unit 1 to a plurality of units in the y-direction.

In such case, when the semiconductor laser 10 in the divided mounting units 20A-20E, 21A-21C is damaged, only the divided mount unit having the damaged semiconductor laser 10 should be replaced. In addition, when the number of the semiconductor laser is needed to be increased or decreased, only the corresponding divided mount unit can be replaced.

The x-direction steering optic element and the y-direction steering optic element 4 that correspond to the two-dimensional deflection optic element of the present invention consist of a group of rhomboid prisms made of a clear medium such as glass and quartz and so forth and change the traveling direction of the laser beam, and more specifically, deflect each laser optic axis of the two-dimensional laser mount unit 1 to the x-direction and y-direction.

FIG. 5 is a block diagram illustrating the x-direction steering optic element of the combined-wave laser light sources according to the aspect of the Embodiment 1 of the present invention. Referring to FIG. 5, a plurality of beam shaping optic elements 11x1-11x5, 12x1-12x5 and a plurality of rhomboid prisms 30x1-30x5 consisting of the group of rhomboid prisms are arranged facing a plurality of semiconductor lasers 10x1-10x5 (in such example, the number thereof is five, but not limited thereto).

In addition, the direction of the optic axis of the laser light of the semiconductor laser 10x3 coincides with the direction of the optic axis of the light beam passing the steering optical element 3a, 4a, and the laser light of the semiconductor laser 10x3 is directly incident to the combining lens 5 through the collimate lenses 14a, 14b without passing a rhomboid prism.

The plurality of beam shaping optic elements 11x1-11x5, 12x1-12x5 shapes the laser lights from the plurality of semiconductor laser 10x1-10x5 and guides the shaped laser lights to the plurality of rhomboid prisms 30x1-30x5.

The plurality of rhomboid prisms 30x1-30x5 consisting of rhombic rectangular-parallelepiped deflect-crank the laser lights from the plurality of semiconductor lasers 10x1-10x5 to guide to the collimate lenses 14a, 14b.

The rhomboid prisms 30x1, 30x5 are the longest rhomboid prisms and are arranged corresponding to the semiconductor lasers 10x1, 10x5, and the rhomboid prisms 30x2, 30x4 are the second longest rhomboid prisms and are arranged corresponding to the semiconductor lasers 10x2. 10x4.

According to the above aspects, the laser lights from the plurality of semiconductor lasers 10x1-10x5 is guided to the collimate lenses 14a, 14b and then the combining lens 5 through the beam shaping optic elements 11x1-11x5, 12x1-12x5 and the plurality of rhomboid prisms 30x1-30x5.

The combining lens 5 plays a role as a converging lens and converges the laser lights passing through the plurality of rhomboid prisms 30x1-30x5 and the collimate lenses 14a, 14b to be incident to the optical fiber 6.

In addition, a cylindrical lens system can be applied thereto instead of the plurality of the beam shaping optic elements 11x1-11x5, 12x1-12x5.

In addition, given the laser lights from the plurality of semiconductor laser 10x1-10x5 could be directly guided to the plurality of rhomboid prisms 30x1-30x5 without shaping the light beams from the plurality of semiconductor lasers 10x1-10x5, the plurality of the beam shaping optic elements 11x1-11x5, 12x1-12x5 may be non-mandatory.

FIG. 6 is a detail block diagram illustrating the y-direction steering optic element of the combined-wave laser light sources according to the aspect of the Embodiment 1 of the present invention. Referring to FIG. 6, collimate lens 15a, 15b and a plurality of rhomboid prisms 40y1-40y5 consisting of the group of rhomboid prisms are arranged facing a plurality of y-direction semiconductor lasers 10y1-10y5 (in such example, the number thereof is five, but not limited thereto).

The collimate lenses 15a, 15b collimate the laser beams from a plurality of semiconductor laser 10y1-10y5 and guides the collimated laser beams to a plurality of rhomboid prisms 40y1, 40y2, 40y4, 40y5. In addition, the optic axis of the laser light of the semiconductor laser 10y3 coincides with the optic axis of the optical fiber 6, and the laser light of the semiconductor laser 10y3 is directly guided to the combining lens 5 without passing the rhomboid prism.

The plurality of rhomboid prisms 40y1. 40y2, 40y4, 40y5 consisting of rhombic rectangular parallelepiped deflect-crank the laser lights from the plurality of semiconductor lasers 10y1-10y5 to guide to the collimate lenses 15a, 15b.

The rhomboid prisms 40y1, 40y5 arranged corresponding to the semiconductor lasers 10y1, 10y5 are longer, and the rhomboid prisms 40y2, 40x4 arranged corresponding to the semiconductor lasers 10y2, 10y4 are shorter.

According to the above aspects, the laser lights from the plurality of semiconductor lasers 10y1-10y5 can be guided to the combining lens 5 through the collimate lenses 15a, 15b followed by the plurality of rhomboid prisms 40y1, 40y2, 40y4, 40y5.

According to the combined-wave laser light sources based on the aspect of the Embodiment 1 of the present invention, the two-dimensional laser mount unit 1 that are arranged on the two-dimensional plane can limit an optic axis adjustment on the two-dimensional laser mount unit 1 on the same plane, so that the optic axes of the two-dimensional laser mount unit 1 can be easily adjusted. Accordingly, the cost for such adjustment can be cut.

In addition, the x-direction steering optic element 3 and y-direction steering optic element 4 deflect each laser optic axis of the two-dimensional laser mount unit 1 in the x-direction and y-direction, so that the combining lens 5 converges the laser lights from the x-direction steering optic element 3 and y-direction steering optic element 4 to be combined to the optical fiber 6. Accordingly, the light beam can be highly densified (increased in concentration).

In addition, the semiconductor laser 10 and the collimate lenses 11 are unified and the unified semiconductor laser 10 and collimate lenses 11 can be shifted in the right-and-left direction in the same plane to adjust the positions of the semiconductor laser 10 and the collimate lenses 11 so that the laser light from the semiconductor laser 10 can be guided to the through-hole 13.

In addition, according to the conventional aspect illustrated in FIG. 10A of the Patent Document 2, the optical path difference between the semiconductor laser LD1 and the semiconductor laser LD 7 is large, so that the beam broadens.

In contrast, referring to FIG. 5 according to the present invention, the semiconductor laser 10x1, 10x2 and the semiconductor laser 10x4, 10x5 are symmetrical to each other. Therefore, the optical path difference between the semiconductor laser 10x1 and the semiconductor laser 10x2 is smaller. Therefore, the beam broadening is much less. The difference between the beam shapes of the semiconductor lasers is smaller.

### Embodiment 2

FIG. 7A-FIG. 7C are diagrams illustrating the structure of a combined-wave laser light sources according to the aspect of the Embodiment 2 of the present invention. FIG. 7A is a plan view illustrating the combined-wave laser light source, FIG. 7B is a cross section view of the laser light sources including laser modules 1a, 1b, and FIG. 7C are cross section views of the mirror 8 and the deflection combined element 9a.

Referring to FIG. 7A, for example, each two of four laser modules 1a-1d (corresponding to the two-dimensional laser mount unit) are arranged in the x-direction (horizontal direction) and in the y-direction of the y-direction (vertical direction), are mounted. For example, 15 semiconductor lasers 10, e.g., 3 of the semiconductor lasers in the x-direction and of the semiconductor lasers in the y-direction, are mounted to each of the laser modules 1a-1d.

Referring to FIG. 7B, the combined-wave laser light source comprises a first laser light source consisting of the laser module 1a, the x-direction steering optic element 3a, the y-direction steering optic element 4a and the prism 7a and a second laser light source consisting of the laser module 1b, the x-direction steering optic element 3b, the y-direction steering optic element 4b and the prism 7b. The mirror 8 is installed between the first laser light source and the second laser light source.

The laser light from the semiconductor laser 10 in the laser module la is respectively deflected to the x-direction by the x-direction steering optic element 3a and to the y-direction by the y-direction steering optic element 4a and guided to the prism 7a. The prism 7a deflects 180-degrees the deflected laser light from the laser module 1a to guide to the mirror 8.

On the other hand, the laser light from the semiconductor laser 10 in the laser module 1b is respectively deflected to the x-direction by the x-direction steering optic element 3b and to the y-direction by the y-direction steering optic element 4b and guided to the prism 7b. The prism 7b deflects 180-degrees the deflected laser light from the laser module 1b to guide to the mirror 8.

Referring to FIG. 7C, the mirror 8 reflects the laser lights from the prism 7a and the laser light from the prism 7b to guide to the deflection combined-wave element 9a.

In addition, with respect to the laser modules 1c, 1d as well as the aspect referring to FIG. 7B, the combined-wave laser light source comprises a third laser light source consisting of the laser module 1c, the x-direction steering optic element 3c, the y-direction steering optic element 4c and the prism 7c and a fourth laser light source consisting of the laser module 1d, the x-direction steering optic element 3d, the y-direction steering optic element 4d and the prism 7d. The deflection combined-wave element 9a is installed between the third laser light source and the fourth laser light source.

The laser light from the semiconductor laser 10 in the laser module 1c is respectively deflected to the x-direction by the x-direction steering optic element 3c and to the y-direction by the y-direction steering optic element 4c and guided to the prism 7c. The prism 7c deflects 180-degrees the deflected laser light from the laser module 1c to guide to the deflection combined-wave element 9a.

On the other hand, the laser light from the semiconductor laser 10 in the laser module 1d is respectively deflected to the x-direction by the x-direction steering optic element 3d and to the y-direction by the y-direction steering optic element 4d and guided to the prism 7d. The prism 7d deflects 180-degrees the deflected laser light from the laser module 1d to guide to the deflection combined-wave element 9a via the wave plate 9b.

The deflection combined-wave element 9a combines the laser lights from the mirror 8 and a wave plate 9b and guides the combined-wave to the fiber 6 via the lens 5a.

According to the combined-wave laser light sources based on the aspect of the Embodiment 2 of the present invention, the laser light from the laser module 1a-1d is deflected by the x-direction steering optic element 3a-3d and the y-direction steering optic element 4a-4d and reversed 180-degrees by deflection of the prism 7a-7d, and then such laser lights are converged by the converging lens 5a to be combined to the optical fiber 6. Specifically, the direction of the optic axis of the light beam passing the prism 7a, 7b reverses 180-degrees relative to the light axis of the laser light.

In addition, the laser light from the laser module 1a, 1b and the laser light from the laser module 1c, 1d are combined, so that a high-power laser can be generated. Particularly, the wavelengths of all laser modules 1a-1d are specified to be the same, so that the high-power laser can be generated while keeping the two-dimensional array.

In addition, each of the laser module 1a-1d can be specified to have a different wavelength from one another. Accordingly, a multi-color laser can be brought into reality.

In addition, when any abnormality relative to the semiconductor laser 10 takes place, only the laser module having the troubled semiconductor laser 10 can be replaced.

FIG. 8 is a block diagram illustrating the x-direction steering optic element of the combined-wave laser light sources according to the aspect of the alternative example of the Embodiment 1 of the present invention. Referring to FIG. 8, with respect to the alternative example of the x-direction steering optic element, the rhomboid prisms 30x1-30x5 as the x-direction steering optic element in FIG. 5 are replaced with a 45-degrees prism pair 31, 32.

Each of the 45-degrees prism pair 31, 32 that is made of 45-degrees triangle-shaped prism is facing to each other, and the laser light propagates from one 45-degrees prism to the other 45-degrees prism by which the laser light is deflect-cranked.

Even when such 45-degrees prism pair 31, 32 is applied, in addition to that the same effect as the rhomboid prisms 30x1-30x5 can be provided, the 45-degrees prism pair 31, 32 is small, so that the cost therefor can be much less.

FIG. 9 is a block diagram illustrating the x-direction steering optic element of the combined-wave laser light sources according to the aspect of the other alternative example of the Embodiment 1 of the present invention. Referring to FIG. 9, with respect to the other alternative example of the x-direction steering optic element, the rhomboid prisms 30x1-30x5 as the x-direction steering optic element in FIG. 5 are replaced with a 45-degrees prism mirrors 33, 34.

Each of the 45-degrees prism mirrors 33, 34 that is made of 45-degrees triangle-shaped mirror is facing to each other, and the laser light propagates from one 45-degrees prism mirror to the other 45-degrees prism mirror by which the laser light is deflect-cranked.

Even when such 45-degrees prism mirrors 33, 34 is applied, in addition to that the same effect as the rhomboid prisms 30x1-30x5 can be provided, the 45-degrees prism mirrors 33, 34 are small, so that the cost therefor can be much less.

### INDUSTRIAL APPLICABILITY

The present invention is applicable to a high-power combined-wave laser light source for a laser machining device and a laser illumination device and so forth.

Although only a few embodiments have been disclosed in detail above, other embodiments are possible and the inventors intend these to be encompassed within this specification. The specification describes certain technological solutions to solve the technical problems that are described expressly and inherently in this application. This disclosure describes embodiments, and the claims are intended to cover any modification or alternative or generalization of these embodiments which might be predictable to a person having ordinary skill in the art.

Also, the inventors intend that only those claims which use the words “means for” are intended to be interpreted under 35 USC 112, sixth paragraph. Moreover, no limitations from the specification are intended to be read into any claims, unless those limitations are expressly included in the claims. The description and drawings contain sufficient structures and arrangements for one of skill in the art to understand the meanings and structures intended and used herein.

Having described at least one of the preferred embodiments of the present invention with reference to the accompanying drawings, it will be apparent to those skills that the invention is not limited to those precise embodiments, and that various modifications and variations can be made in the presently disclosed system without departing from the scope or spirit of the invention. Thus, it is intended that the present disclosure cover modifications and variations of this disclosure provided they come within the scope of the appended claims and their equivalents.

1. A combined-wave laser light source, comprising:
a two-dimensional laser light source in which a plurality of laser light sources is arranged two-dimensionally along a common plane;
a two-dimensional deflection optic element that is arranged corresponding to said two-dimensional laser light source and comprises an x-direction steering optic element that deflects each laser optic axis of said two-dimensional laser light source in an x-direction and a y-direction steering optic element that deflects each laser optic axis of said two-dimensional laser light source in a y-direction; and
a combining lens that converges the laser lights from said two-dimensional deflection optic element to combine said laser lights to an optical fiber;
wherein said plurality of laser light sources is in-place so that a center position between said plurality of laser light sources in each direction is approximately a center position of said combing lens, each direction steering optic element has a length corresponding to a distance between said center position and said laser light sources that are in-place, and lights from said laser light sources are introduced to a proximity of the center of said combining lens.

2. The combined-wave laser light source, according to claim 1, wherein:
each said laser light source has a unified collimate lens, and a unified laser light source is arranged two-dimensionally in said two-dimensional laser light source.

3. The combined-wave laser light source, according to claim 2, wherein:
said two-dimensional laser light sources are plurally divided in said x-direction and said y-direction.

4. The combined-wave laser light source, according to claim 1, wherein:
said two-dimensional deflection optic element comprises a rhomboid prism.

5. The combined-wave laser light source, according to claim 1, wherein:
said two-dimensional deflection optic element further comprises a 45-degrees prism pair.

6. The combined-wave laser light source, according to claim 1, wherein:
said two-dimensional deflection optic element comprises a 45-degrees prism mirror.

7. A combined-wave laser light source: comprising:
a two-dimensional laser light source in which a plurality of laser light sources are arranged two-dimensionally along a common plane;
a two-dimensional deflection optic element that is arranged corresponding to said two-dimensional laser light source and has an x-direction steering optic element that deflects each laser optic axis of said two-dimensional laser light source in an- x-direction and a y-direction steering optic element that deflects each laser optic axis of said two-dimensional laser light source in a y-direction;
a plurality of prisms that deflect 180-degrees each said laser optic axis and forms the said plurality of two-dimensional deflection optic elements; and
a combining lens that converges the laser lights from said two-dimensional deflection optic element to combine said laser lights to an optical fiber.

8. The combined-wave laser light source, according to claim 7, wherein:
each one of said plurality of two-dimensional laser light sources has different wavelength from each other.
